(19) United States
(12) Patent Application Publication
(10) Pub. No.: US 2004/0251506 A1
(43) Pub. Date: Dec. 16, 2004

(54) Hall effect devices, memory devices, and hall effect device readout voltage increasing methods

(76) Inventors: Mark B. Johnson, Springfield, VA (US); Gary A. Prinz, Alexandria, VA (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 10/457,704

(22) Filed: Jun. 10, 2003

(51) Int. Cl. H01L 21/00; H01L 29/76

(52) U.S. Cl. 257/421; 257/422; 438/48; 257/295

(57) ABSTRACT

Hall Effect devices, memory devices, and Hall Effect device readout voltage increasing method. A hall effect device includes a conductive film layer capable an electrical current, a ferromagnetic layer having a configurable orientation and configured to cover a portion of the conductive film layer such that fringe magnetic fields can be generated by an edge portion of the ferromagnetic layer, a high permeability magnetic layer disposed below the conductive film layer. The fringe magnetic fields are drawn toward the high permeability magnetic layer such that the magnetic fields pass though the conductive film layer to enable closure of the magnetic fields.

### FIELD OF THE INVENTION

This invention generally relates to memory devices. At least some embodiments of the invention relate to Hall effect devices, memory devices, and hall effect device readout voltage increasing methods.

### BACKGROUND OF THE INVENTION

Hall plates have long been used as magnetic field sensors to measure fields that are homogeneous over the area of the plate. There are also numerous devices that combine ferromagnetic films along with Hall plates. In a typical configuration, the Hall plate is embedded, by an appropriate doping technique, vertically (i.e. perpendicular to the substrate surface) in a semiconducting substrate. A ferromagnetic film is fabricated outside the region of the Hall plate, and is used to “focus” the flux of an external magnetic field onto the vertical Hall plate.

The disadvantages of this device, which is used as a sensor with linear response, include limited sensitivity along with increased cost of the device. The sensitivity may be limited because the enhancement ratio of the magnetic field at the focus of the ferromagnetic layer relative to the applied field is relatively small. Moreover, the geometry of the device does not permit a memory effect while preventing the device from being implemented practically as a memory element.

### SUMMARY OF THE INVENTION

At least some embodiments of the invention relate to Hall effect devices, memory devices, and hall effect device readout voltage increasing methods.

In one aspect, a hall effect device comprising a conductive film layer capable of carrying an electrical current, a ferromagnetic layer having a configurable magnetization orientation and configured to cover a portion of the conductive film layer such that fringe magnetic fields can be generated by an edge portion of the ferromagnetic layer, a high permeability magnetic layer disposed below the conductive film layer, and wherein the fringe magnetic fields are drawn towards the high permeability magnetic layer such that the magnetic fields pass through the conductive film layer to enable closure of the magnetic fields.

In another aspect, a memory device comprising a first layer disposed on a second layer capable of carrying an electrical current, the first layer covering a portion of the second layer, a third layer disposed below the second layer, and wherein fringe magnetic fields generated at an edge of the first layer are drawn towards the third layer and pass through the second layer, thereby increasing a readout voltage of the memory device.

In a further aspect, a hall effect device comprising a conductive film layer capable of carrying an electrical current, a ferromagnetic layer having a configurable magnetization orientation and configured to cover a portion of the conductive film layer such that fringe magnetic fields can be generated by an edge portion of the ferromagnetic layer, one or more ferromagnetic components formed in close proximity to an edge of the ferromagnetic layer, and wherein the conductive film layer is patterned using a mesa etch such that the one or more ferromagnetic components are located substantially beneath the level of the conductive film layer, and fringe magnetic fields generated from the edge of the ferromagnetic layer are drawn towards the one or more ferromagnetic components such that the magnetic fields pass through the conductive film layer to enable closure of the magnetic fields.

In yet another aspect, a hall effect device readout voltage increasing method comprising forming a conductive film layer capable of carrying an electrical current, forming a ferromagnetic layer to cover the conductive film layer such that fringe magnetic fields can be generated by an edge portion of the ferromagnetic layer, and forming a high permeability magnetic layer below the conductive film layer such that the fringe magnetic fields are drawn towards the high permeability magnetic layer and pass through the conductive film layer thereby increasing the readout voltage.

Other aspects of the invention are disclosed herein as is apparent from the following description and figures.

### DESCRIPTION OF THE DRAWINGS

Preferred embodiments of the invention are described below with reference to the following accompanying drawings.

FIG. 1 is a schematic representation of an exemplary Hybrid Hall Effect (HHE) device.

FIG. 2 is a perspective view of a hybrid Hall Effect device according to one embodiment.

FIG. 3 is a cross-sectional view of a portion of the HHE device according to another embodiment and showing an element with high magnetic permeability that can be used to facilitate magnetic flux return and also to increase the perpendicular component of magnetic field in an active region of the HHE device.

FIG. 4 is a top view of the HHE device and showing a ferromagnetic component with a preferred shape anisotropy and two lateral elements of high magnetic permeability used to facilitate magnetic flux return in accordance with one embodiment.

FIG. 5 is a cross-sectional view of a portion of HHE device according to another embodiment.

### DETAILED DESCRIPTION OF THE INVENTION

This disclosure of the invention is submitted in furtherance of the constitutional purposes of the U.S. Patent Laws“to promote the progress of science and useful arts” (Article 1, Section 8).

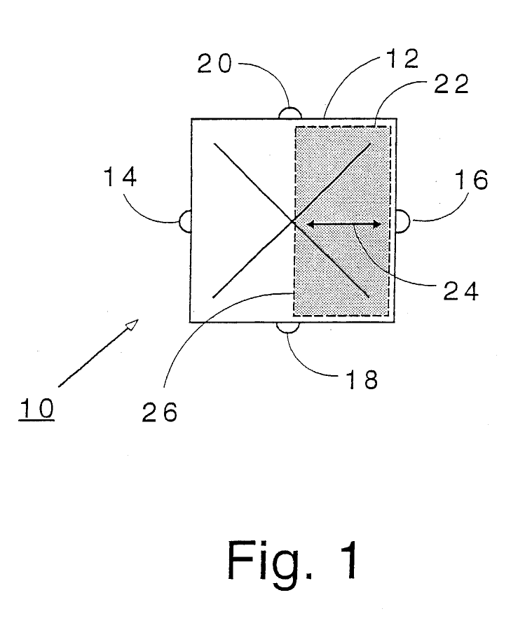

Referring to FIG. 1, there is shown an exemplary circuit schematic of the hybrid Hall Effect (HHE) device according to an exemplary embodiment of the present invention. The HHE device 10 includes a Hall plate 12 having terminals 14, 16, 18, and 20, the Hall plate 12 being cross-centered in a square. The Hall plate 12 is alternatively referred to as a carrier channel 12. Terminals 14 and 16 are used for current bias I+ or I− or voltage bias, and the terminals 18, 20 are used as sense probes S1 and S2 for sensing a bipolar Hall voltage (or current). The device 10 includes a ferromagnetic film 22 which is electrically isolated from the Hall plate 12. Magnetization 24 of the film 22 is typically in the plane of the film 22 and lies along an axis parallel with that of the bias current. Magnetic material may also be used for film 22 with magnetization perpendicular to the plane. In a preferred embodiment, the film 22 covers a portion of the area of the Hall plate 12 such that an edge 26 of the film 22 is over a central region of the Hall plate 12. Other arrangements of arranging the film 22 over the Hall plate 12 are possible.

In the case where magnetization is parallel to the plane of the film 22, the magnetization may have two stable states along the axis parallel with the bias current, and each state corresponds to “up” or “down” fringe fields near the edge of the film 22, a positive or negative Hall voltage (or current), and a binary bit of information “1” or “0”.

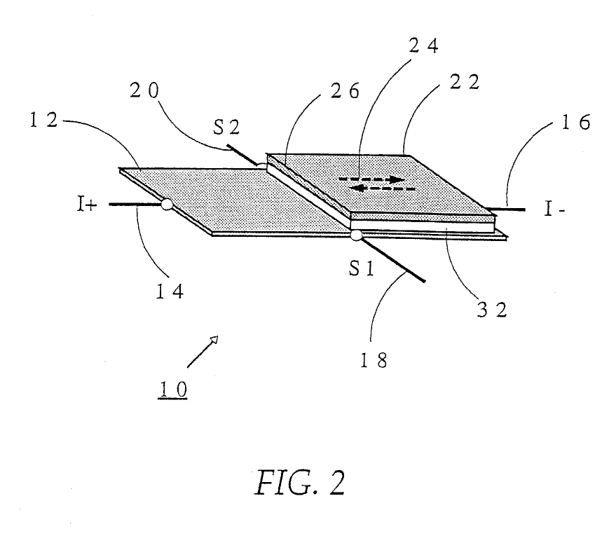

FIG. 2 shows a perspective view of the HHE device shown in FIG. 1 according to one embodiment. The ferromagnetic film 22 is electrically isolated from the Hall plate 12 by an insulating layer 32. In a preferred embodiment, the ferromagnetic film 22 covers a portion of the area of the Hall plate 12 such that an edge 26 of the film 22 is over a central region of the Hall plate 12. In one embodiment, the insulating layer 32 may cover the portion of the Hall plate 12 that is directly beneath the film 22. In another embodiment, the insulating layer 32 may cover all of the Hall plate 12 and may serve the additional function of passivating portions of the device 10 offering protection against degradation during after processing.

The film 22 may be fabricated as one component of a bilayer or a multilayer, where a second layer may be a thin magnetic (ferromagnetic or antiferromagnetic) layer used to magnetically bias a first layer. The result of the magnetic bias can be a larger remanence or a hysteresis loop that is not symmetric with respect to zero applied field. Other layers for example, in the multilayer, may be buffer layers that may be used to improve the quality of growth of the ferromagnetic layer and/or bias layer, or a passivation layer for protecting the multilayer from environmental degradation. The film 22 may be fabricated from a nonmetallic compound in order to achieve a specific operational advantage. For example, device 10 made with a ferrite as the ferromagnetic film 22 was found to achieve faster switching times.

In order to achieve larger readout voltages or currents, the Hall plate 10 may also be fabricated using materials with mobilities larger than those of Si or GaAs. Further details are set forth in co-pending Navy Cases 83,835 and 83,836 having U.S. application Ser. Nos. 10/176,002 filed on Jun. 21, 2002, and 10/126,664, filed on Apr. 22, 2002, respectively, the entire contents of which are incorporated herein by reference.

Local and fringe magnetic fields from the edge 26 of the ferromagnetic film 22 are perpendicular to the plane of the Hall plate 12 may point “up” or “down” depending on the orientation of the magnetization of the film 22, and have an average readout, value of Bₐᵥ in the active region of the device 10. In an exemplary embodiment, for constant bias current, the sensed Hall voltage or current has opposite polarity when the fringe fields are“up” compared with when they are “down.” The magnetization state 24 may be written (set) to be positive or negative by using the magnetic field associated with a positive or negative current pulse transmitted down an integrated wire (not shown) that is contiguous with the film 22, and described in U.S. Pat. No. 5,652,445 to Johnson, the entire contents of which are incorporated herein by reference.

The local magnetic fields at the edge 26 of the film 22 provide the mechanism that enables operation of the device 10. The magnitude of these fields is proportional to the saturation magnetization Mₛ of the film 22, and output of the device 10 is thus proportional to the value of Mₛ.

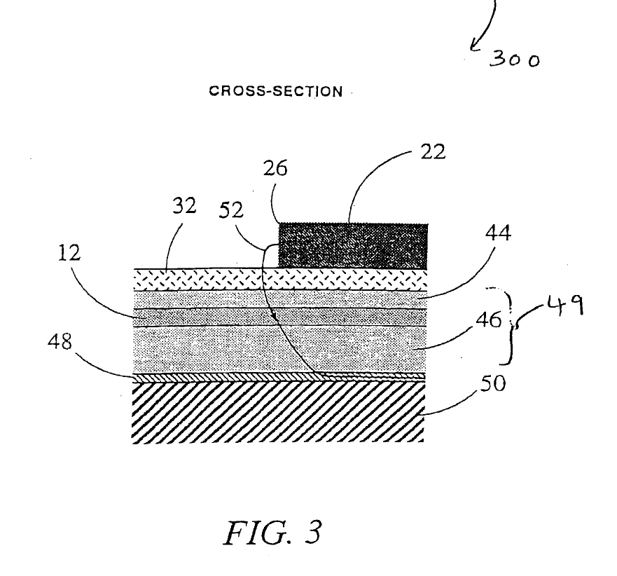

FIG. 3 is a cross-sectional view of a portion of the HHE device showing an element 48 with high magnetic permeability that can be used to facilitate magnetic flux return and also to increase the perpendicular component of magnetic field in an active region of the HHE device in accordance with another embodiment of the present invention. The HHE device 300 includes a material of high magnetic permeability deposited as a layer 48 on a substrate 50. The substrate may be made of Si or GaAs. The high magnetic permeability layer 48 may be deposited under or in a buffer layer 46. In one exemplary embodiment, layer 48 is a Permalloy, such as Ni_{0.8}Fe_{0.2}.

A carrier channel 12 is grown on top of the buffer layer 46 (e.g., insulating layer) and functions as a hall plate. In one embodiment, the buffer layer 46, the hall plate 12, and insulating layer 44 are grown at the same time and in the sequence as illustrated in FIG. 3. Layers 46, 12, and 44 are together referred to as a heterostructure 49 that includes a two-dimensional electron gas (2DEG). Another insulating layer 32 is optionally grown on insulating layer 44. A ferromagnetic film 22 is grown either directly on the insulating layer 44 or on the optionally grown insulating layer 32.

In certain instances, when the heterostructure 49 is grown, the insulating layer 44 may become incompatible with the growth of the ferromagnetic film 22 on it, and in such instances, the optional insulating layer 32 may be grown on top of the insulating layer 44.

The local, magnetic fringe field at an edge 26 of the ferromagnetic film 22 generates a voltage (or current) signal that enables an operation of the HHE device 300. As the size of the ferromagnetic film 22 shrinks, the region of high field magnitude is restricted to a volume very close to the edge 26 of the film 22. As a result, the field Bₐᵥ present at the plane of the carriers can be diminished. The inventors have determined that stray magnetic field lines from film 22 may be preferentially directed down towards the layer of carriers (e.g., carrier channel 12) by using the high permeability magnetic element layer 48 that facilitates closure of the magnetic flux. A plurality of magnetic field lines is referred to herein as magnetic flux.

Referring again to FIG. 3, a single magnetic field line 52 is shown as originated at the edge 26 of the film 22 and is drawn downwards to the high permeability material 48. The field line 52 closes to an opposite end of film 22. Although a single field line is illustrated, it will be appreciated that a plurality of magnetic field lines (e.g., magnetic flux lines) may originate at the edge 26. By forcing the magnetic flux lines downward toward the high magnetic permeability layer 48, such magnetic flux lines are made to pass through the carrier channel 12, thereby increasing the magnitude of the perpendicular component of flux lines at the plane of the carrier channel 12. Since the perpendicular component provides the Lorentz force which in turn provides the readout voltage (Bₐᵥ), the readout voltage (Bₐᵥ) is thereby increased.

It will be appreciated that for an application involving an array of individual devices 300, the high magnetic permeability layer 48 would be individually patterned and aligned beneath each film 22. The magnetic state of the film 22 would be set by fringe fields from write pulses applied to an integrated write wire (not shown), and coupling to the high magnetic permeability layer 48 would be so weak that the write process would not be affected. In one embodiment as shown in FIG. 3, it may be possible to fabricate the high magnetic permeability layer 48 as a continuous layer. The material of the high magnetic permeability layer 48 would break into domains, with a domain associated with each film 22 in an array of such elements associated with respective individual devices 300. The walls at the edges of the domains may generate fringe fields that could degrade device performance. In some devices, it may not be possible to find an appropriate material that can be grown under or as a part of the buffer layer 46. However, it would still be possible to provide a magnetic element for flux closure. The Hall Effect device 300 described above may be used as a memory device.

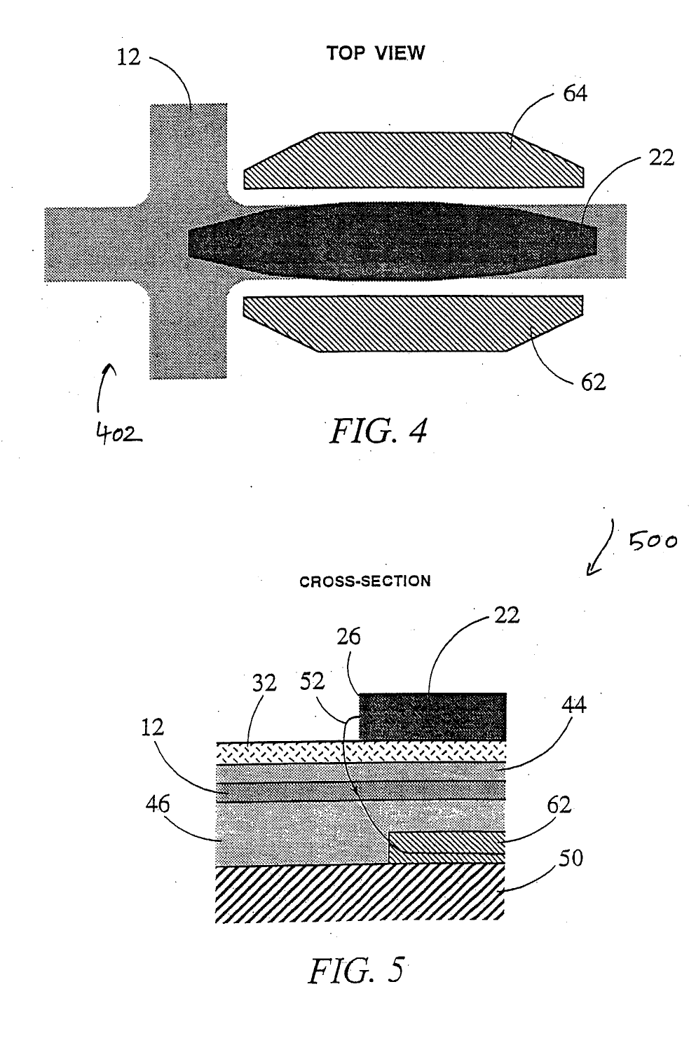

Referring to FIG. 4, there is shown a top view of the HHE device and illustrating a ferromagnetic component with preferred shape anisotropy and two lateral elements of high magnetic permeability used to facilitate magnetic flux return in accordance with one embodiment. FIG. 4 includes a Hall plate 12, with Hall cross 402, and a ferromagnetic film 22 grown on the hall plate 12. One or more ferromagnetic components 62, 64 may be fabricated in close proximity to the film 22 for facilitating magnetic flux return.

FIG. 5 is a cross-sectional view of a portion of HHE device according to another embodiment. In an exemplary case, the Hall cross 402 (FIG. 4) may be patterned using a mesa etch that etches through the insulating layers 32, 44, the carrier channel 12, which functions as a Hall plate, and the buffer layer 46, to a surface of the substrate 50. The mesa etch might etch only a small distance past the interface between the carrier channel 12 and the buffer layer 46. The ferromagnetic element 62 facilitating flux closure may then be microfabricated such that it is substantially beneath the level of the carrier channel 12. Although FIG. 5 illustrates only one ferromagnetic component 62, it will be appreciated that a second ferromagnetic component 64 may be used when further focusing of magnetic flux lines (i.e., a plurality of magnetic field lines 52) is desired. Appropriate materials for the ferromagnetic element(s) 62 or 64 include Permalloy (e.g., Ni_{0.8}Fe_{0.2}). The field lines 52 from the edge 26 of the film 22 are drawn downwards towards the ferromagnetic element 62, thereby increasing the magnitude of the perpendicular component of field at the plane of the carrier channel 12 (Bₐᵥ) and thus increasing a readout voltage of the Hall Effect device 500. It may be beneficial to planarize the Hall Effect device 500 prior to fabrication of write wires (not shown).

Although FIG. 5 shows ferromagnetic component 62 as formed on the surface of the substrate 50, the ferromagnetic component 62 may be fabricated in any portion of the buffer layer 46 without making contact with the carrier channel 12. Likewise, the ferromagnetic film 22 may be formed on the insulating layer 44 and insulating layer 32 may be desirable in circumstances as described above.

Shape anisotropy may be used to reduce the coercivity and therefore reduce the amplitude of current in the write pulse that sets the magnetization state of the ferromagnetic film 22. A variety of magnetic anisotropies may be used to influence the magnetic characteristics of the ferromagnetic film 22. One design criteria involves shape anisotropy. In one example, the inventors have determined that a long rectangle, with an aspect ratio of about 5 to 1, promotes formation of an easy magnetization axis along the long axis of the rectangle resulting in low coercivity and high remanence. In another example, the inventors have determined that an ellipse, with a similar aspect ratio of about 4 to 1 results in slightly lower coercivities than a rectangle.

The inventors have fabricated prototype cells appropriate for very large scale integration (VLSI) with Permalloy and cobalt films with dimensions approximately equal to 1 micron by 5 microns. Prototype cells appropriate for ultra large scale integration (ULSI) were fabricated with Permalloy films with dimensions approximately equal to 0.5 microns by 2.5 microns. In one embodiment, the film 22 has been drawn with a shape approximating an ellipse.

The inventors have determined that a ULSI prototype with a Permalloy film has achieved a coercivity of 25 Oe with a very high remanence.

It will be appreciated that the HHE device of the present invention may also be used in any Hall Effect Device, such as for example, magnetic sensitive field effect transistor (MAGFET), the magnetotransistor, or any other Hall Effect sensing device.

Various advantages of the HHE device of the present invention include suitability of the HHE device for use in high density memory and logic environments. An exemplary aspect of the present invention presents novel materials systems to be used in the fabrication of HHE devices with the effect of enhancing the operating speed and increasing the output signal level of the device. In another aspect, the present invention achieves substantial improvement over existing HHE devices because the remanence of the magnetic component layer is larger and therefore the bistable output voltage or current is larger. HHE device of the present invention also has advantages over existing HHE devices as the hysterisis loop of the ferromagnetic component is square, thus contributing to the efficiency of the write process. The coercivity of the ferromagnetic component is smaller, thereby lowering the power of the write process, the perpendicular component of the magnetic field is increased in the active region of the device, thereby increasing the output voltage or current. The switching times of the ferromagnetic component layer are smaller, and materials used to fabricate the HHE device are compatible with the fabrication requirements of support circuitry, such as for example, select, sense and amplification circuits.

In compliance with the statute, the invention has been described in language more or less specific as to structural and methodical features. It is to be understood, however, that the invention is not limited to the specific features shown and described, since the means herein disclosed comprised preferred forms of putting the invention into effect. The invention is, therefore, claimed in any of its forms or modifications within the proper scope of the appended claims appropriately interpretec in accordance with the doctrine of equivalents.

What is claimed is:

1. A Hall Effect device comprising:
a conductive film layer capable of carrying an electrical current;
a ferromagnetic layer having a configurable magnetization orientation and configured to cover a portion of the conductive film layer such that fringe magnetic fields can be generated by an edge portion of the ferromagnetic layer;
a high permeability magnetic layer disposed below the conductive film layer; and
wherein the fringe magnetic fields are drawn towards the high permeability magnetic layer such that the magnetic fields pass through the conductive film layer to enable closure of the magnetic fields.

2. The device of claim 1, wherein the high permeability magnetic layer is disposed on a substrate and configured to increase a magnitude of a perpendicular component of the fringe magnetic fields thereby increasing a read out voltage of the hall effect device.

3. The device of claim 1, wherein the high permeability magnetic layer is formed as a continuous layer to cover a full length of the substrate.

4. The device of claim 1, wherein the high permeability magnetic layer comprises one or more ferromagnetic components on a substrate.

5. The device of claim 2, wherein an electrical signal is generated in response to the fringe magnetic fields acting on the electrical current in the conductive film layer.

6. The device of claim 1, further comprising:
a buffer layer disposed between the high permeability magnetic layer and the conductive film layer, and wherein the high permeability magnetic layer comprises Permalloy.

7. The device of claim 1, wherein the conductive film layer and the ferromagnetic layer are separated by one or more insulating layers.

8. The device of claim 1, wherein the ferromagnetic film is formed in an elliptical shape.

9. A memory device comprising:
a first layer disposed on a second layer capable of carrying an electrical current, the first layer covering a portion of the second layer;
a third layer disposed below the second layer; and
wherein fringe magnetic fields generated at an edge of the first layer are drawn towards the third layer and pass through the second layer, thereby increasing a readout voltage of the memory device.

10. The device of claim 9, wherein the first layer is a ferromagnetic layer.

11. The device of claim 9, wherein the second layer is a conductive film layer.

12. The device of claim 9, wherein the third layer is a high permeability magnetic layer comprising Ni_{0.8}Fe_{0.2} permalloy.

13. The device of claim 9, further comprising:
a buffer layer disposed between the second layer and the third layer.

14. The device of claim 9, wherein the second layer and the first layer are separated by one or more insulating layers.

15. The device of claim 9, wherein the third layer is formed on a substrate as a continuous layer to cover a full length of the substrate.

16. A hall effect device comprising:
a conductive film layer capable of carrying an electrical current;
a ferromagnetic layer having a configurable magnetization orientation and configured to cover a portion of the conductive film layer such that fringe magnetic fields can be generated by an edge portion of the ferromagnetic layer;
one or more ferromagnetic components formed in close proximity to an edge of the ferromagnetic layer; and
wherein the conductive film layer is patterned using a mesa etch such that the one or more ferromagnetic components are located substantially beneath the level of the conductive film layer, and fringe magnetic fields generated from the edge of the ferromagnetic layer are drawn towards the one or more ferromagnetic components such that the magnetic fields pass through the conductive film layer to enable closure of the magnetic fields.

17. The device of claim 16, further comprising:
a buffer layer located between the conductive film layer and the one or more ferromagnetic components.

18. The device of claim 17, wherein the one or more ferromagnetic components are formed in the buffer layer.

19. The device of claim 16, wherein the one or more ferromagnetic components are configured to increase a magnitude of a perpendicular component of the fringe magnetic fields thereby increasing a read out voltage of the hall effect device.

20. The device of claim 16, wherein the ferromagnetic film is formed in an elliptical shape.

21. The device of claim 16, wherein the hall effect device is a memory device.

22. A hall effect device readout voltage increasing method comprising:
forming a conductive film layer capable of carrying an electrical current;
forming a ferromagnetic layer to cover the conductive film layer such that fringe magnetic fields can be generated by an edge portion of the ferromagnetic layer; and
forming a high permeability magnetic layer below the conductive film layer such that the fringe magnetic fields are drawn towards the high permeability magnetic layer and pass through the conductive film layer thereby increasing the readout voltage.

23. The method of claim 22, further comprising:
forming a buffer layer between the conductive film layer and the high permeability magnetic layer.

24. The method of claim 23, further comprising:
forming one or more insulating layer between the conductive film layer and the ferromagnetic layer.

25. The method of claim 23, wherein the high permeability magnetic layer is formed in the buffer layer.

26. The method of claim 22, wherein the high permeability magnetic layer is formed as a continuous layer to cover a full length of a substrate on which the high permeability magnetic layer is formed.

27. The method of claim 22, wherein the high permeability magnetic layer comprises one or more ferromagnetic components on a substrate.

28. The method of claim 27, wherein the conductive film layer is patterned using a mesa etch such that the one or more ferromagnetic components are located substantially beneath the level of the conductive film layer, and fringe magnetic fields generated from the edge of the ferromagnetic layer are drawn towards the one or more ferromagnetic components such that the magnetic fields pass through the condutive film layer to enable closure of the magnetic fields thereby increasing a readout voltage of hall effect device.
